(19) United States
(12) Patent Application Publication
(10) Pub. No.: US 2010/0102429 A1
(43) Pub. Date: Apr. 29, 2010

(54) FLIP-CHIP PACKAGE STRUCTURE WITH BLOCK BUMPS AND THE WEDGE BONDING METHOD THEREOF

(75) Inventor: CHUNG HSING TZU, TAIPEI COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: GREAT TEAM BACKEND FOUNDRY, INC., TORTOLA (VG)

(21) Appl. No.: 12/358,645

(22) Filed: Jan. 23, 2009

Related U.S. Application Data
(60) Provisional application No. 61/108,025, filed on Oct. 24, 2008.

(51) Int. Cl. H01L 23/52; B23K 31/02; B23K 1/06

(52) U.S. Cl. 257/690; 228/199; 228/193; 228/110.1; 257/E23.141

(57) ABSTRACT

A flip-chip block structure with block bumps comprises a die, a substrate, a first block bump, and a second block bump. The die comprises an active side and a backside, a first die pad and a second die pad are disposed on the active surface, and an electrode layer is disposed on the backside. The first die pad and the second die pad are connected to the pattern side of the substrate via the first block bump and the second block bump respectively. Besides, the first block bump and the second block bump are formed by a wedge bonding method, therefore, the block bumps are more easily formed into larger sizes, which enhance electrical performance and thermal dissipation performance of the flip-chip structure due to a lower contact resistance and a larger contact area between the die and the substrate.

### CROSS REFERENCE TO RELATED APPLICATIONS

This application claims priority of U.S. Provisional Application No. 61/108,025 filed on 24 Oct. 2008 under 35 U.S.C. §119(e), the entire contents of which are all hereby incorporated by reference.

### FIELD OF THE INVENTION

The present invention relates to a flip-chip package structure with block bumps and the wedge bonding method thereof. The block bumps are easier to be formed into a larger size, which will enhance the electrical performance and the thermal dissipation performance of the flip-chip package structure.

### BACKGROUND OF THE INVENTION

Flip-chip interconnection technology has been widely applied to the current semiconductor package filed, which is advantageous in reducing the package size and shortening of the signal conduction path. The most commonly used chip package structures applying the flip-chip interconnection technology comprise the Flip-Chip Ball Grid Array (FCBGA) and the Flip-Chip Pin Grid Array (FCPGA).

Referring to FIG. 1A and FIG. 1B, there are shown a top view of the wire stud bumps on the die of the prior art and a side view of the flip-chip package structure with the wire stud bumps of the prior art.

The flip-chip package structure 100 comprises a die 11, a substrate 13, and a plurality of wire stud bumps 15.

Wherein the die 11 comprises a die bond pad 11 and an active side 112, the die bond pad 111 is disposed on the active side 112.

The substrate 13 comprises a substrate side 132; the substrate side 132 has a plurality of lead layout patterns. Further, the wire stud bumps 15 are electrically connected between the die bond pad 111 and the lead layout pattern on the substrate side 132, so that the signal produced by the die 11 can be conducted electrically to the substrate 13 via the wire stud bumps 15.

Regarding the flip-chip structure 100 of the prior art, the die bond pad 111 is electrically connected to substrate 13 via the wire stud bumps 15. Because the wire stud bumps 15 are made by a gold wire thermal-sonic bonding technology, the price is lower than a wafer bumping technology. However, the wire stud bumps 15 use wire ball bonding technology in bumping size and shapes, and therefore can only be constrained to a round shape. So, the wire stud bumps 15 of the constrained shapes will limit electrical performance and thermal dissipation performance when a lower interconnection contact resistance and a more efficient thermal dissipation are needed.

### SUMMARY OF THE INVENTION

It is the primary objective of the present invention to provide a flip-chip package structure with block bumps and the wedge bonding method thereof, in which the block bumps can be designed as any desired rectangular bumping size based on the special electrical requirement of the die.

It is the secondary objective of the present invention to provide a flip-chip package structure with block bumps and the wedge bonding method thereof, the block bumps are more easily formed into the larger sizes, which reduce the contact resistance and increase the contact area between the die and the substrate, so as to enhance the electrical performance and thermal dissipation performance of the flip-chip package structure.

To achieve the above mentioned and other objectives, the present invention provides a flip-chip package structure with block bumps, comprising: a substrate comprising a pattern side; a die comprising an active side and a backside, a first die bond pad and a second die bond pad disposed on the active side; a first block bump connecting the first die bond pad and the pattern side of the substrate; and a second block bump connecting the second die bond pad and the pattern side of the substrate.

The present invention further provides a flip chip package structure, comprising: a substrate comprising a pattern side; a die comprising an active side, and a die bond pad disposed on the active side; and a block bump electrically connecting the die bond pad and the pattern side of the substrate; wherein the block bump is formed by wedge bonding.

The present invention further provides a wedge bonding method to form a block bump on a die with a die bond pad, comprising: providing a metal wire; forming a wedge bond on the die bond pad of the die by wedge bonding the metal wire; and breaking the connection between the metal wire and the wedge bond to form the block bump.

### BRIEF DESCRIPTION OF THE DRAWINGS

FIG. 1A shows a top view of the wire stud bumps on the die of the prior art.

FIG. 1B shows a side view of the flip-chip package structure with the wire stud bumps of the prior art.

FIG. 2A shows a top view of the block bumps on the die of a preferred embodiment of the present invention.

FIG. 2B shows a side view of the flip-chip package structure with the block bumps of a preferred embodiment of the present invention.

FIG. 3A shows a top view of the block bumps on the die of an embodiment of the present invention.

FIG. 3B shows a side view of the flip-chip package structure with the block bumps of an embodiment of the present invention.

FIG. 4 shows the wedge-bonding device of a wedge bonding method of the present invention.

FIGS. 5A and 5B show the bonding process of a wedge bonding method of the present invention.

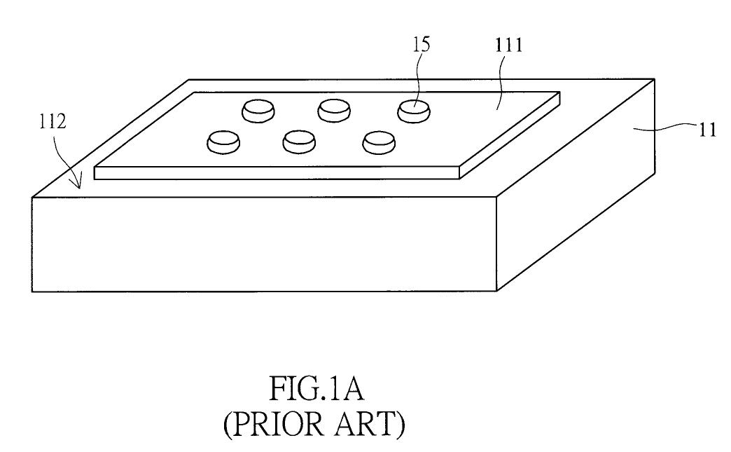

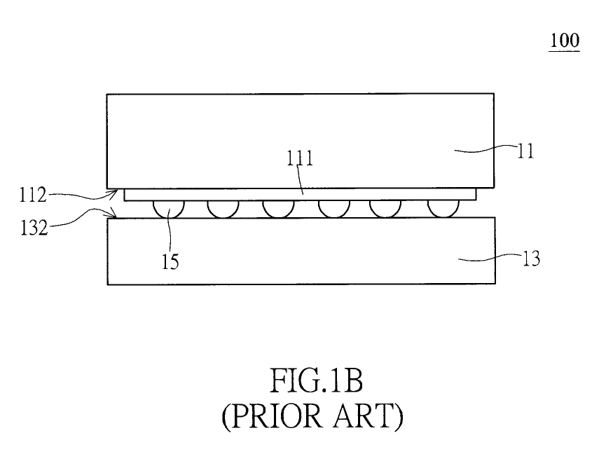

### DETAILED DESCRIPTION OF THE INVENTION

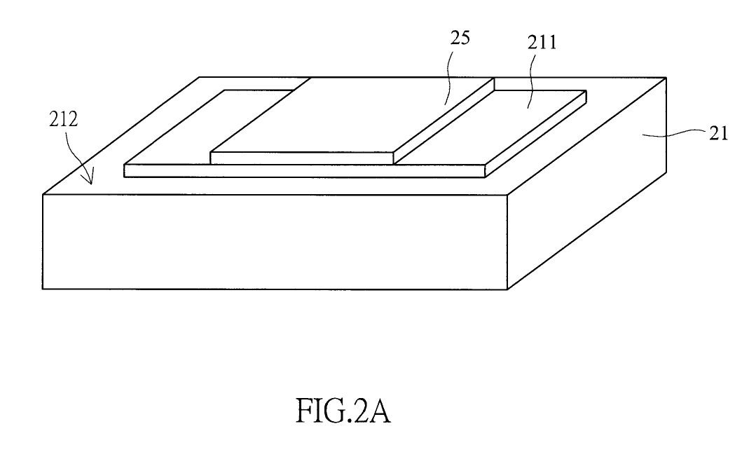

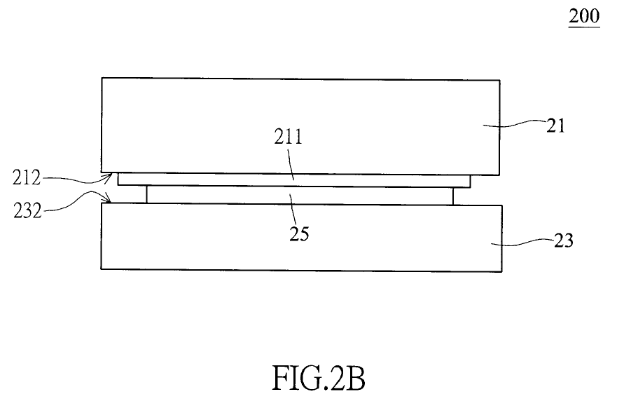

Referring to FIG. 2A and FIG. 2B, there are shown a top view of the block bumps on die and a side view of the flip chip package structure with the block bumps of a preferred embodiment of the present invention.

The flip-chip package structure 200 comprises a die (also known as a chip) 21, a substrate 23 (such as the print circuit board), and a block bump 25. Wherein the die 21 comprises an active side 212 and a die bond pad 211, the die bond pad 211 is an electrode pad (aluminum material pad) that is disposed on said active side 212.

The substrate 23 comprises a pattern side 232; the pattern side 232 has a plurality of lead layout patterns. Further, the die bond pad 211 is electrically connected to the lead layout pattern of the substrate 23 via the block bump 25. Generally, the flip chip technology requires to form under bump metal on the bond pads (or I/O pads), however, in the invention, the block bump 25 can be directly connected to the die bond pad 211 and requires no under bump metal (UBM). Therefore, the electrical signal generated by the die 21 can successfully conduct to the substrate 23. Besides, the block bump 25 is selected as an aluminum wire and ribbon, a gold wire and ribbon, or another wire and ribbon of a specific metal-type.

The block bump 25 of the present invention is formed in bumping size and shapes by the wedge bonding method, and therefore can form larger bump than the wire stud bump (15) of the prior art. Besides, the block bump 25can form block (regional) bumps whereas the wire stud bump (15) can only form round bumps.

Furthermore, the block bump 25 can be designed to any desired rectangular bumping size based on the special electrical requirement, so as to enhance the electrical performance and the thermal dissipation performance of the flip-chip package structure 200. For example, the die bond pad 211 is regarded as a power bond pad, so that the size of the die bond pad 211 needs the larger one, and the size of it's corresponding block bump 25 is relatively larger, thus, they can provide a larger current conductive area and a lower contact resistance, and so as to improve the electrical performance of the flip-chip package structure 200. Further, since the size of the die bond pad 211 and the block bump 25 are larger, the thermal conductive area is also increased, and so as to improve the thermal dissipation performance of the flip-chip package structure 200 after it is packaged.

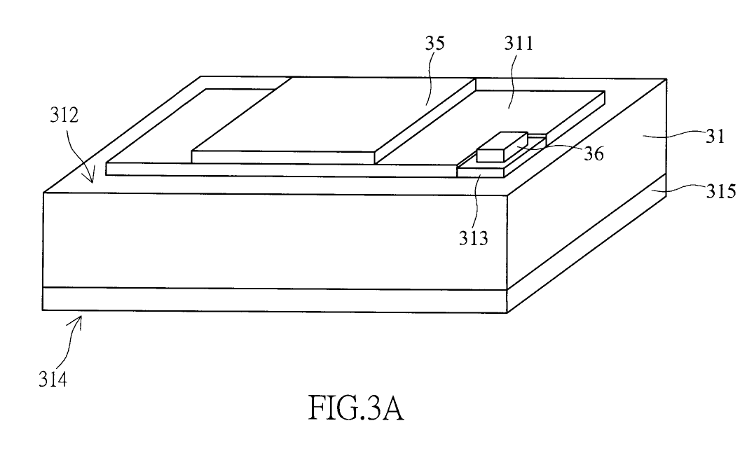

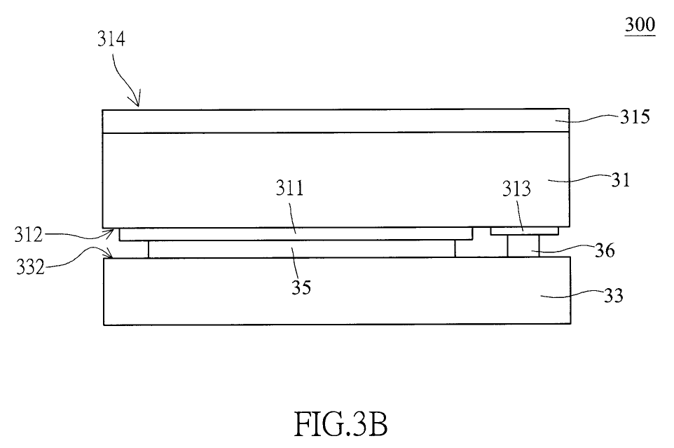

Referring to FIG. 3A and FIG. 3B, there are shown a top view of the block bumps on die and a side view of the flip chip package structure with the block bumps of the present invention.

The flip-chip package structure 300 of the present invention is further applied in power transistor field. The flip-chip package structure 300 comprises a die 31, a substrate 33, a first block bump 35, and the second block bump 36.

Wherein the die 31 comprises an active side 312 and a backside 314, a first die bond pad 311 and a second die bond pad 313 are disposed on said active side 312, and an electrode layer 315 is disposed on said backside 314. The first die bond pad 311 is a source electrode pad (aluminum material pad), the second die bond pad 313 is a gate electrode pad (aluminum material pad), the electrode layer 315 is a drain electrode layer, and the size of the first die bond pad 311 is larger than the size of the second die bond pad 313.

The substrate 33 comprises a pattern side 332; the pattern side 332 has a plurality of lead layout patterns. Further, the first die bond pad 311 is electrically connected to the lead layout pattern of the substrate 33 via the first block bump 35, the second die bond pad 313 is electrically connected to the lead layout pattern of the substrate 33 via the second block bump 36.

Similarly, the first/second block bump 35/36 can be directly connected to the first/second die bond pad 311/313 and requires no under bump metal. In addition, the size of the first block bump 35 is larger than the size of the second block bump 36, the first block bump 35 and the second block bump 36 are selected as an aluminum wire and ribbon, a gold wire and ribbon, or another wire and ribbon of a specific metal-type.

The first block bump 35 and the second block bump 36 of the present invention are formed in rectangular bumping size and shapes by the wedge bonding method, and therefore can form larger bumps than the wire stud bump (15) of the prior art, so as to enhance the electrical performance and the thermal dissipation performance of the flip-chip package structure 300. The innovation of the invention is to eliminate the limitation of the wire stud bumping technology of the prior art but remain at a lowest cost.

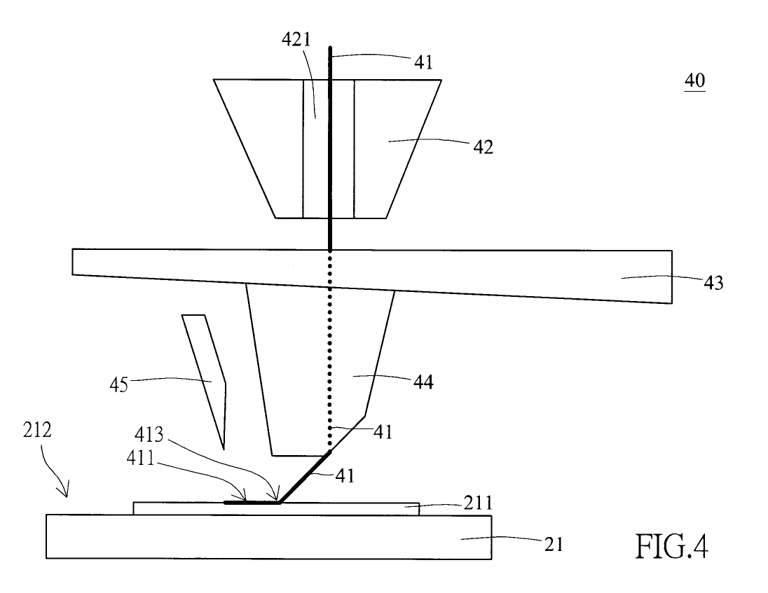

Referring to FIG. 4, there is shown the wedge bonding device of a wedge bonding method of the present invention.

The wedge bonding device 40 comprises a metal wire 41 (or a metal ribbon), a damper 42, an ultrasonic transducer 43, and a wedge bonding tool 44. Wherein the metal wire 41 is clamped into the damper 42, the damper 42 comprises a passageway 421, and the clamper 42 operates the metal wire 41 within the passageway 421. The metal wire 41 through the passageway 421 is further connected to the ultrasonic transducer 43. Then, the ultrasonic transducer 43 feeds the metal wire 41 to the wedge bonding tool 44, so as to bond the metal wire 41 to the die bond pad 211 of the die 21 along the wedge bonding tool 44, and therefore can form a wedge bond 411 on the die bond pad 211. Besides, the wedge bond 411 formed by the wedge bonding that is completed by a metal diffusion technology. The diffusion technology can adopt an ultrasonic bonding, a thermal-sonic bonding or a thermal-compress bonding way. The wedge device 40 further comprises a cutter 45. The cutter 45 can cut the neck 413 of the wedge bond 411 after the wedge bond 411 is bonded to the die bond pad 211 of the die 21, so as to cut and break off the connection between the wire 41 and the wedge bond 411 to form the block bump 25.

Naturally, the wedge bonding method of the present invention can be applied to the die (31) of FIG. 3A and FIG. 3B, so as to form the first block bump (35) or the second block bump (36).

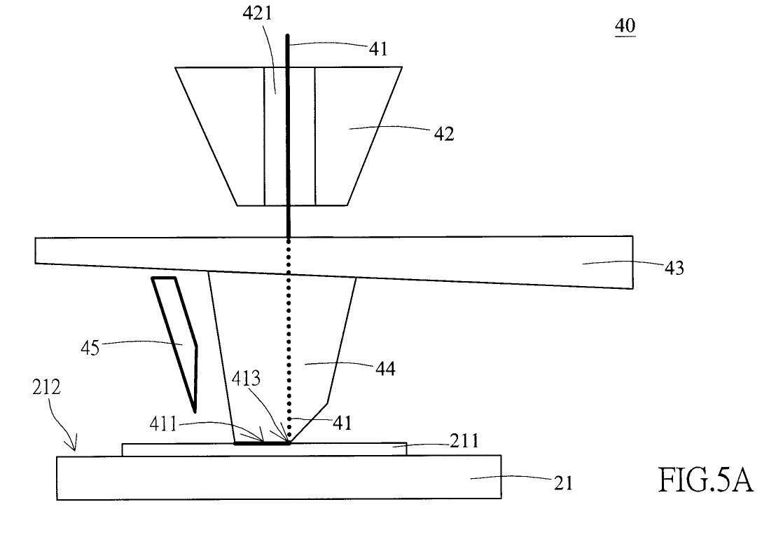

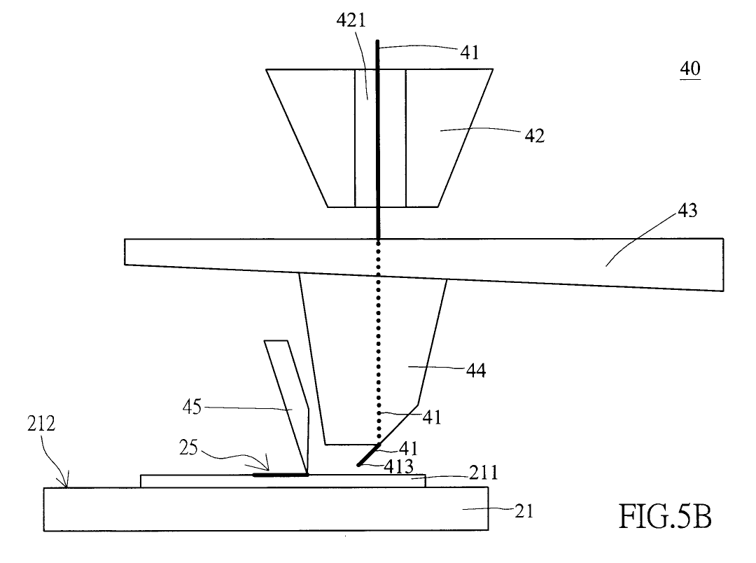

Referring to FIGS. 5A and 5B, there are shown the bonding process of a modified wedge bonding method of the present invention.

Firstly, as shown in FIG. 5A, the wedge bonding device 40 is lowered onto the die bond pad 211 of the die 21, and proving a metal wire 41 to the die bond pad 211 of the die 21, which will be formed the wedge bond 411 on the die bond pad 211 of the die 21 by the wedge bonding. As shown in FIG. 5B, the cuter 45 will execute a cutting movement after the wedge bond 411 is formed on the die bond pad 211 of the die 21. The cutter 45 is lowered into the neck 413 of the wedge bond 411, which cuts and breaks off the connection between the wire 41 and the neck 413 of the wedge bond 411. Finally, the wedge-bonding device 30 can be disconnected from the die bond pad 211 of the die 21, such as to form the block bump 25.

While this invention has been particularly shown and described with reference to the preferred embodiments thereof, it will be understood by those skilled in the art that various changes in form and details may be made without departing from the spirit and scope of the invention.

What is claimed is:

1. A flip chip package structure with block bumps, comprising:
a substrate comprising a pattern side;
a die comprising an active side and a backside, a first die bond pad and a second die bond pad disposed on said active side;
a first block bump connecting said first die bond pad and said pattern side of said substrate; and
a second block bump connecting said second die bond pad and said pattern side of said substrate.

2. The flip-chip package structure of claim 1, wherein said flip-chip package structure is applied in power transistor field.

3. The flip-chip package structure of claim 1, wherein the size of said first die bond pad is larger than the size of said second die bond pad.

4. The flip-chip package structure of claim 1, wherein said first die bond pad is a source electrode pad.

5. The flip-chip package structure of claim 1, wherein said second die bond pad is a gate electrode pad.

6. The flip-chip package structure of claim 1, wherein an electrode layer is disposed on said back side and said electrode layer is a drain electrode layer.

7. The flip-chip package structure of claim 1, wherein the size of said first block bump is larger than the size of said second block bump.

8. The flip-chip package structure of claim 1, wherein the material of said first block bump and said second block bump are selected as an aluminum wire and ribbon, a gold wire and ribbon, or another wire and ribbon of specified metal type.

9. The flip chip package structure of claim 1, wherein said first block bump and said second block bump can be directly connected to said first die bond pad and said second bond pad that are without under bump metal.

10. The flip-chip package structure of claim 1, wherein said first block bump and said second block bump can be designed as any desired rectangular bumping size and shape based on the special electrical requirement of the die.

11. A flip chip package structure, comprising:
a substrate comprising a pattern side;
a die comprising an active side, and a die bond pad disposed on said active side; and
a block bump electrically connecting said die bond pad and said pattern side of said substrate;
wherein said block bump is formed by wedge bonding.

12. The flip chip package structure of claim 11, wherein the block bump is directly connected to the die bond pad.

13. The flip-chip package structure of claim 11, wherein the material of said block bump is selected as an aluminum wire and ribbon, a gold wire and ribbon, or another wire and ribbon of specified metal type.

14. The wedge bonding method to form a block bump on a die with a die bond pad, comprising: providing a metal wire; forming a wedge bond on the die bond pad of the die by wedge bonding said metal wire; and breaking the connection between the metal wire and the wedge bond to form the block bump.

15. The wedge bonding method of claim 14, wherein the wedge bond formed by the wedge bonding is completed by a metal diffusion technology.

16. The wedge bonding method of claim 15, wherein the metal diffusion technology adopts an ultrasonic bonding, a thermal-sonic bonding or a thermal-compress bonding.
